(19) United States
(12) Patent Application Publication
(10) Pub. No.: US 2004/0070046 A1
(43) Pub. Date: Apr. 15, 2004

(54) Reliable dual gate dielectrics for MOS transistors

(76) Inventor: Hiroaki Niimi, Richardson, TX (US)

Correspondence Address: TEXAS INSTRUMENTS INCORPORATED, P O BOX 655474, M/S 3999, DALLAS, TX, 75265

(21) Appl. No.: 10/270,758

(22) Filed: Oct. 15, 2002

(51) Int. Cl. H01L 29/00

(52) U.S. Cl. 257/510

(57) ABSTRACT

Dual gate dielectric layers are formed on a semiconductor substrate for MOS transistor fabrication. Initial dielectric layers are formed on a semiconductor substrate (10). The initial layers are removed in regions of the substrate and a third dielectric layer (160) is formed in these regions. Forming the third dielectric layer (60) modifies the initial dielectric layers and results in final dielectric layers (170, 180). MOS transistors are then fabricated using the dielectric layers (160) (170, 180).

### FIELD OF THE INVENTION

The present invention relates to a method for forming dual gate (or split gate) dielectrics for integrated circuit MOS transistors using chemical vapor deposition and thermal/non-thermal oxidation and/or nitridation.

### BACKGROUND OF THE INVENTION

High performance integrated circuits often require metal oxide semiconductor (MOS) transistors to operate at different voltages. Given the electric field constraints required for reliable transistor operation, different operating voltages will require that the MOS transistors on the same integrated circuit be formed with more than one gate dielectric thickness. For example a 0.18 μm gate length transistor designed to operate at 1.8 volts may require a gate dielectric thickness of 38 Å while a 0.5 μm gate length transistor designed to operate at 3.3 volts will require a gate dielectric thickness of 65 Å.

Shown in FIG. 1 are two MOS transistors 110 and 120 with differing gate dielectric thickness. The semiconductor substrate 10 can comprise epitaxial layers and/or buried insulator structures. The isolation structure 20 is a shallow trench isolation (STI) structure and is formed using standard processing technology. Other isolation structures such as localized oxidation of silicon (LOCOS) can also be used. To form the gate dielectric layers 30 and 40 a split gate process can be used. In the split gate process a first dielectric layer is grown on the surface of the semiconductor substrate 10. The region of the first dielectric layer that will eventually form the dielectric layer 40 is masked using a patterned photomask and the unmasked regions of the first dielectric layer removed. Following the removal of the patterned photomask the dielectric layer 30 is formed. Formation of dielectric layer 30 comprises thermally growing the dielectric layer. During the growth process addition dielectric layer thickness is added to the remaining first dielectric layer resulting in dielectric layer 40 being formed. For the transistors described above the dielectric layer 30 for the lower voltage transistor 110 will be about 38 A thick and the dielectric layer 40 for the higher voltage transistor 120 will be about 65 A thick. Following the formation of the dielectric layers 30 and 40, the gate structures 50 and 60 of the MOS transistors are formed. If source and drain extension regions are required these are formed at this time by implanting the required dopant species into the semiconductor substrate aligned to the edge of the gate structures 50 and 60. Sidewall structures 70 and 80 are formed adjacent to the gate structures 50 and 60 followed by the formation of the source and drain regions 90 and 100.

As the current size of the MOS transistors is reduced the thickness of the gate dielectric layers used to form these transistors must also be reduced to ensure proper operation. The transistor gate leakage current is related to the thickness of the dielectric layer increasing with a reduction in dielectric layer thickness. For the thinner gate dielectric layer (i.e., 30 in FIG. 1) techniques such as the addition of nitrogen to the dielectric layer have been used to reduce the transistor gate leakage current. Previously the thickness of the dielectric layer for the higher voltage transistor has been such that no special techniques were required to keep the gate leakage current for these transistors below acceptable levels. However as the transistors continue to scale downwards gate leakage currents from the high voltage transistors 120 with the thicker dielectric layers 40 is becoming a serious limitation to integrated circuit performance. There is therefore a need for a method to simultaneously optimize both dielectric layers for reduced gate leakage current while reducing the dielectric layer thickness.

### SUMMARY OF INVENTION

The instant invention is a method for forming multiple gate dielectrics with different thickness. The method comprises forming first and second dielectric layers on a semiconductor substrate. The first dielectric layer can comprise silicon oxide or silicon oxynitride formed using thermal or plasma techniques. The second dielectric layer can comprise a CVD silicon oxynitride layer formed using thermal or plasma chemical vapor deposition techniques. Using masking techniques, the two dielectric layers are removed from regions of the substrate and a third dielectric layer grown in the regions from which the first and second dielectric layers were removed. The third dielectric layer can comprise plasma nitrided silicon oxide. MOS transistors are formed using the different dielectric layers.

### BRIEF DESCRIPTION OF THE DRAWINGS

For a more complete understanding of the present invention and the advantages thereof, reference is now made to the following description taken in conjunction with the accompanying drawings, wherein like reference numerals represent like features, in which:

FIG. 1 is a cross-sectional diagram showing MOS transistors with different gate dielectric layer thickness.

FIGS. 2(a)-2(c) are cross-sectional diagrams showing an embodiment of the instant invention.

FIG. 3 is a cross-sectional diagram showing MOS transistors with different gate dielectric layer thickness according to an embodiment of the instant invention.

### DETAILED DESCRIPTION OF THE INVENTION

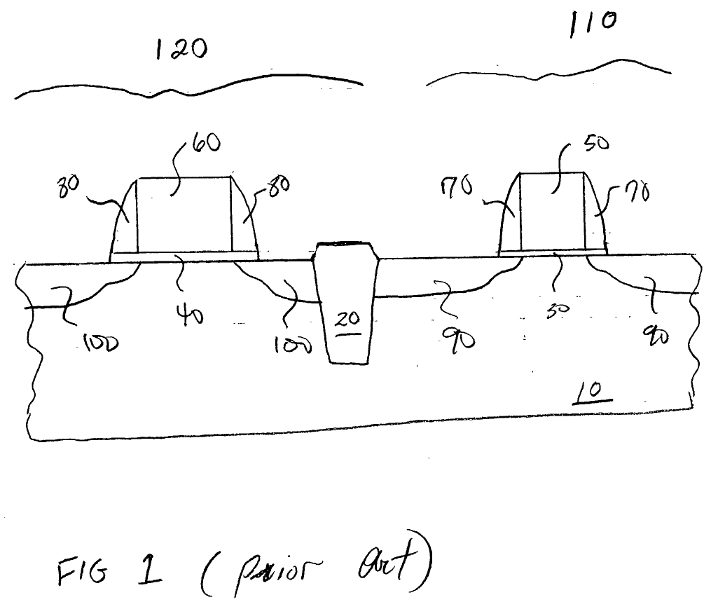

The semiconductor substrate 10 shown in FIG. 1 can comprise a bulk substrate, an epitaxial layer, and/or a buried insulator layer. Isolation structures 20 formed in the substrate 10 can comprise STI structures, LOCOS isolation or any other suitable isolation scheme or structure. Following the formation of the isolation structures 20 and any additional processes, a first dielectric layer 130 is formed on the substrate surface. In a first embodiment of the instant invention a thermal oxidation process is used to form a first dielectric layer 130 of silicon oxide. The thermal oxidation process comprises oxidation temperatures of 700° C. to 1000° C. at pressures of 0.1 Torr to 100 Torr using gases from the group comprising O₂, O₃, N₂O, NO, O₂/N₂, N₂O/N₂ or NO/N₂ along with any other suitable gases. The silicon oxide thickness so formed will be between 0.5 nm to 1.5 nm. In a second embodiment of the instant invention a plasma oxidation process can be used to form the first dielectric layer 130. Such a process can be performed at temperatures up to 700° C. at power levels of 50 watts to 2000 watts using RF or microwave plasma excitation. Gases such as O₂, N₂O, NO, O₂/N2, N2O/N2 or NO/N2 can be used to perform the oxidation in a He, Ar, Xe, or Kr plasma. The silicon oxide thickness so formed will be between 0.5 nm to 1.5 nm.

Following the formation of the first dielectric layer 130, a second dielectric layer 140 of silicon oxynitride is formed using either thermal chemical vapor deposition (TCVD) or plasma chemical vapor deposition (PCVD). In a TCVD process oxygen, nitrogen, and silicon source gases are introduced into a suitable thermal CVD reaction chamber. The oxygen source gas can be chosen from O₂, N₂O, NO, O₂/N₂, N₂O/N₂, NO/N₂ or any other suitable gas. The nitrogen source gas can be NH₃ and the silicon source gases SiH₄, Si₂H₄, SiH₂Cl₂ or any other suitable gas. The thermal CVD process is performed at temperatures between 600° C. and 1000° C. at pressures of 0.1 Torr to 100 Torr. This will result in a silicon oxynitride layer 140 containing 5 to 30 atomic percent of nitrogen with a thickness of 0.5 nm to 3.0 nm. In the PCVD process, plasma CVD reaction process chambers with either a RF or a microwave plasma excitation source can be used at power levels between 50 watts and 2000 watts. A He, Ar, Xe, or Kr plasma can be used with 02, N₂O, or NO oxygen sources gases, N₂, N₂O, NO, or NH₃ nitrogen source gases, and SiH₄, Si₂H₄ or SiH₂Cl₂ silicon source gases. The PCVD process will result in a silicon oxynitride layer 140 containing 5 to 30 atomic percent of nitrogen with a thickness of between 0.5 to 3.0 nm.

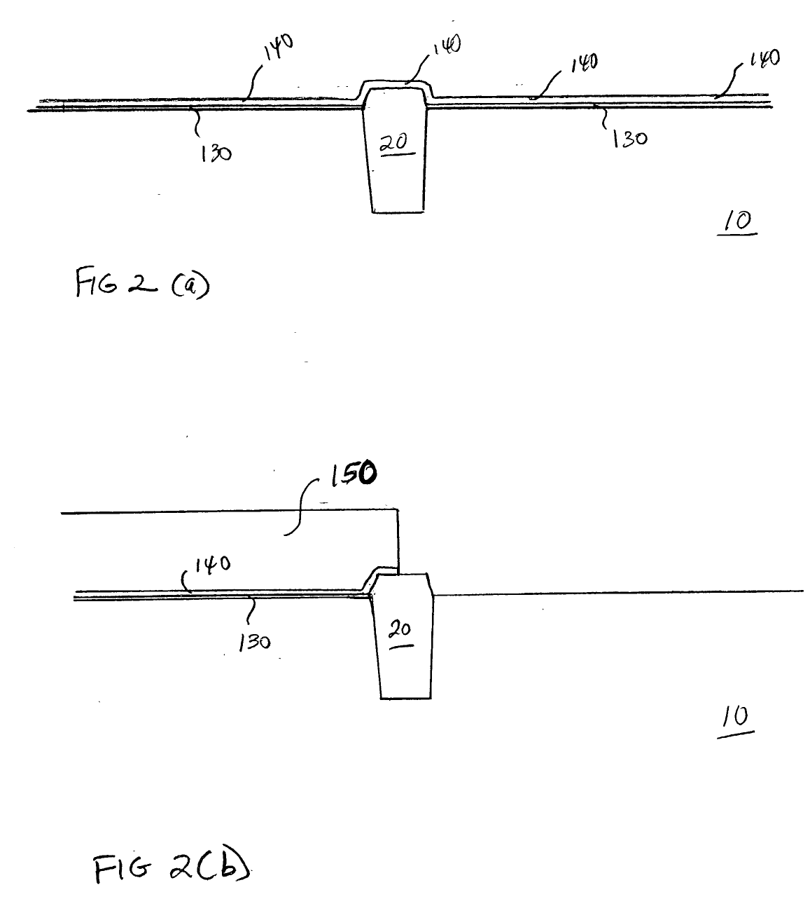

Following the CVD deposition of the second dielectric layer 140 an optional oxidation and/or anneal process can be performed. In a first embodiment an optional post deposition thermal oxidation and anneal process is performed. The substrate shown in FIG. 2(a) containing the second dielectric layer 140 is exposed to O₂, O₃, N₂O, NO, O₂/N₂, N₂O/N₂, NO/N₂, N₂, NH₃, or NH₃/N₂ at temperatures between 500° C. and 1200° C. at pressures between 0.1 Torr to 100 Torr for times between 1 second to about 1 hour. In a second embodiment a post deposition plasma oxidation process is performed. The substrate shown in FIG. 2(a) containing the second dielectric layer 140 is exposed to O₂, O₃, N₂O, NO, or NH₃, in a 50 watt to 2000 watt RF or microwave He, Ar, Xe, or Kr plasma at temperatures up to 700° C. and pressures between 0.01 Torr to 10 Torr.

Following the formation of the second dielectric layer 140 and any subsequent treatments, a patterned photoresist layer 150 is formed over the second dielectric layer as shown in FIG. 2(b). The portions of the first and second dielectric layers not covered by the patterned photoresist layer 150 are then removed using standard techniques. Following the removal of the exposed first and second dielectric layers the patterned photoresist layer is removed.

As shown in FIG. 2(c), a third dielectric layer 160 is formed on the surface of the substrate in those regions where the first and second dielectric layers were removed. In an embodiment of the instant invention the third dielectric layer 160 will comprise a plasma nitrided oxide. The plasma nitrided oxide can be formed using either thermal or plasma oxidation followed by a plasma nitridation. In the thermal oxidation process 0.5 nm to 1.5 nm of silicon oxide is formed at temperatures between 700° C. to 1100° C. at pressures between 0.1 Torr to 100 Torr using gases from the group comprising O₂, O₃, N₂O, NO, O₂/N₂/O₃/N₂, N₂0/N₂, NO/N₂, H₂/O₂, H₂/O₃, H₂/N₂O, H₂/NO, H₂/O₂/N₂, H₂/O₃/N₂, H₂/N₂O/N₂ or H₂/NO/N₂. In the plasma oxidation process 0.5 nm to 1.5 nm of silicon oxide is formed at temperatures up to 700° C. at pressures between 0.01 Torr to 10 Torr in a RF or microwave plasma at power levels between 50 watts to 2000 watts in a He, Ar, Xe, or Kr plasma using gases from the group comprising O₂, O₃, N₂O, NO, O₂/N₂, N₂O/N₂, NO/N₂, H₂/O₂, H₂/O₃, H₂/N₂O, H₂/NO, H₂/O₂/N₂, H₂/N₂O/N₂ or H₂/NO/N₂. Following the formation of the silicon oxide layer a plasma nitridation process is performed. The plasma nitridation process will incorporate 2 to 20 atomic percent of nitrogen into the silicon oxide layer resulting in a plasma nitrided oxide layer 160 with 2 to 20 atomic percent of nitrogen. In the plasma nitridation process the silicon oxide layer is exposed to a RF or microwave He, Ar, Xe, or Kr plasma at power levels between 50 watts and 2000 watts at pressures between 0.1 Torr and 100 Torr using gases from the group comprising N₂, N₂O, NO, or NH₃. Following the plasma nitridation process an optional thermal anneal can be performed. In this process the plasma nitrided oxide 160 is annealed at temperatures between 600° C. to 1200° C. at pressures between 0.1 Torr to 100 Torr in gases from the group comprising O₂, O₃, N₂O, NO, O₂/N₂, O₃/N₂, N₂O/N₂, NO/N₂, N₂, NH₃, or NH₃/N₂. During the formation of the dielectric layer 160, the dielectric layers 130 and 140 are exposed to all the processes and will be transformed to dielectric layers 170 and 180 either by the growth of additional silicon oxide or by the incorporation of addition nitrogen.

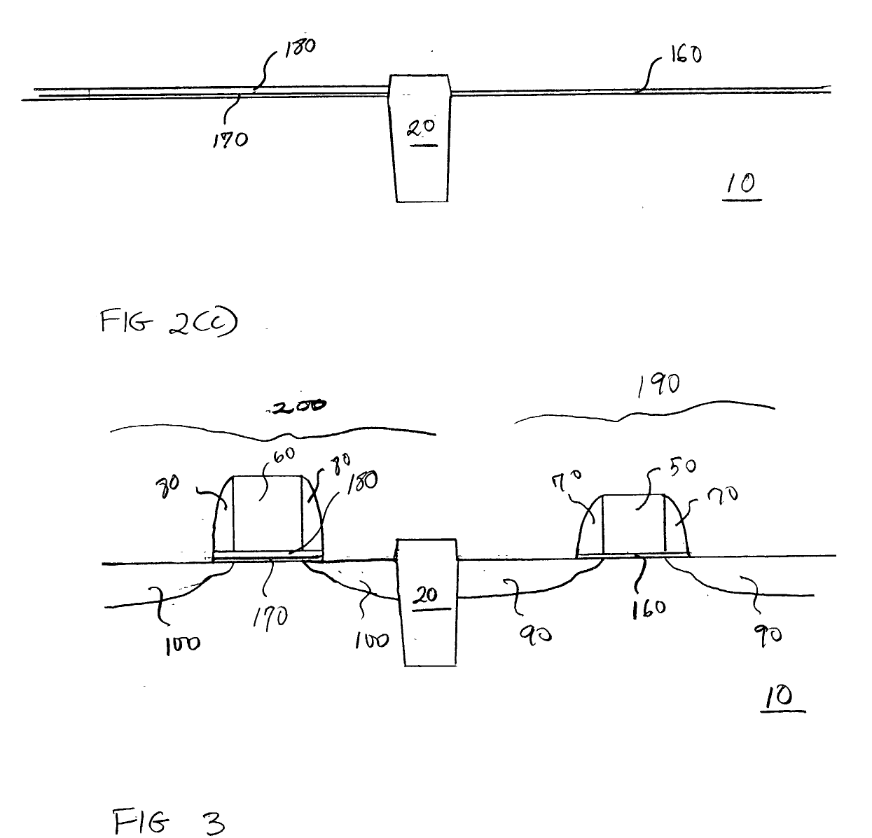

Shown in FIG. 3 are MOS transistors fabricated using the dielectric layers of the instant invention. The MOS transistor 190 formed using the plasma nitrided dielectric layer 160 will operate using the lower voltages and the MOS transistor formed using the dielectric layers 170 and 180 will operate using the higher voltages. Therefore the operating voltage of MOS transistor 190 will be lower than the operating voltage of MOS transistor 200. The gate regions of the transistors 50 and 60 can be formed using polycrystalline silicon or a metal. Any suitable dielectric material can be used to form the sidewall structures 70 and 80 and the source and drain regions 90 and 100 are formed using standard processing techniques.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

We claim:

1. A method for forming MOS transistor gate dielectrics, comprising:
providing a semiconductor substrate;
forming a first dielectric layer on said semiconductor substrate;
forming a second dielectric layer on said first dielectric layer;
removing said second dielectric layer and said first dielectric from a region of said substrate; and
forming a third dielectric layer on said semiconductor substrate in said region from which said first and second dielectric layers were removed.

2. The method of claim 1 wherein said first dielectric layer comprises silicon and oxygen.

3. The method of claim 2 wherein said second dielectric layer is silicon oxynitride.

4. The method of claim 3 wherein said third dielectric layer is a plasma nitrided oxide.

5. The method of claim 3 wherein said silicon oxynitride layer comprises 5 to 30 atomic percent of nitrogen.

6. The method of claim 5 wherein said silicon oxynitride layer is 0.5 nm to 3.0 nm thick.

7. The method of claim 4 wherein said plasma nitrided oxide comprises 2 to-20 atomic percent of nitrogen.

8. A method for forming integrated circuit MOS transistors, comprising:
providing a semiconductor substrate;
forming a first dielectric layer comprising silicon and oxygen;
forming a silicon oxynitride layer on said first dielectric layer;
removing said first dielectric layer and said silicon oxynitride layer from a region of said substrate; and
forming a plasma nitrided oxide layer on said semiconductor substrate in said region from which said first dielectric layer and said silicon oxynitride layer were removed.

9. The method of claim 8 wherein said silicon oxynitride layer comprises 5 to 30 atomic percent of nitrogen.

10. The method of claim 8 wherein said plasma nitrided oxide comprises 2 to 20 atomic percent of nitrogen.

11. Integrated circuit MOS transistors, comprising:
a semiconductor substrate;
a dielectric stack comprising a first and second dielectric layer formed on a first region of said semiconductor substrate;
a third dielectric layer formed on a second region of said semiconductor substrate;
a first transistor gate formed on said dielectric stack; and
a second transistor gate formed on said third dielectric layer.

12. The integrated circuit MOS transistors of claim 11 where said first dielectric layer comprises silicon and oxygen.

13. The integrated circuit MOS transistors of claim 12 where said second dielectric layer comprises silicon oxynitride.

14. The integrated circuit MOS transistor of claim 13 where said third dielectric layer is a plasma nitrided oxide layer.

15. The integrated circuit MOS transistor of claim 14 wherein said silicon oxynitride layer comprises between 5 to 30 atomic percent of nitrogen.

16. The integrated circuit MOS transistor of claim 15 wherein said plasma nitrided oxide comprises between 2 and 20 atomic percent of nitrogen.
